(19) United States
(12) Patent Application Publication
(10) Pub. No.: US 2015/0153609 A1
(43) Pub. Date: Jun. 4, 2015

(54) BOTTOM CHASSIS FOR DISPLAY DEVICE AND DISPLAY DEVICE INCLUDING THE SAME

(71) Applicant: Samsung Display Co., Ltd., Yongin-City (KR)

(72) Inventor: Se Bong KIM, Asan-si (KR)

(73) Assignee: Samsung Display Co., Ltd., Yongin-City (KR)

(21) Appl. No.: 14/274,275

(22) Filed: May 9, 2014

(30) Foreign Application Priority Data
Dec. 4, 2013 (KR) 10-2013-0150086

(51) Int. Cl. G02F 1/1333; H05K 5/00; A47B 81/06; F21V 8/00; G02F 1/1335

(52) U.S. Cl. CPC G02F 1/133308; G02B 6/0081; G02F 1/133512; A47B 81/06; H05K 5/0017; G02F 2001/133314; G02F 2202/28

(57) ABSTRACT

Provided is a bottom chassis for a display device and a display device including the same capable of fixing constituent elements while omitting a mold frame. The bottom chassis for a display device includes: a bottom surface; a plurality of sidewall surfaces extended and bent from the bottom surface; and a plurality of ceiling surfaces extended and bent from the plurality of sidewall surfaces, in which the plurality of ceiling surfaces is extended from two sidewall surfaces which face each other among the plurality of sidewall surfaces.

### CROSS-REFERENCE TO RELATED APPLICATION

This application claims priority to and the benefit of Korean Patent Application No. 10-2013-0150086 filed in the Korean Intellectual Property Office on Dec. 4, 2013, the entire contents of which application are incorporated herein by reference.

### BACKGROUND

(a) Technical Field

The present disclosure of invention relates to a bottom chassis of a display device and to a display device including the same, and more particularly, to a bottom chassis of a display device that has a capability of fixing constituent elements while omitting a mold frame.

(b) Description of Related Technology

Thin panel display devices are often used for computer monitors, televisions, mobile phones, and the like. The thin panel display devices may include a liquid crystal display, a plasma display device, and the like.

The liquid crystal display which is one of the most common types of flat or otherwise thin panel display typically includes two spaced apart substrates with field generating electrodes disposed thereon such as pixel electrodes, a common electrode, and the like, and a liquid crystal layer interposed therebetween. The liquid crystal display generates an electric field through the liquid crystal layer by applying voltages across the field generating electrodes to thereby control alignments of liquid crystal molecules in the liquid crystal layer. The controlled alignments can determine polarization of incident light, which may be used to form displayed images.

Since the liquid crystal display does not self-emit its incident light, the transmissive type of liquid crystal display often requires a backlighting source. In this case, the light source may be an artificial light source which is separately provided or it may be natural light. Commonly used artificial light sources for the liquid crystal display include light emitting diodes (LEDs), cold cathode fluorescent lamps (CCFLs), external electrode fluorescent lamps (EEFLs), and the like.

A light guide plate (LGP) is often used in conjunction with edge lighting light sources so that light emitted from the artificial light sources has uniform luminance on the entire display panel area.

Generally, the liquid crystal display includes a bottom chassis receiving constituent elements such as a display panel, a light source, and a light guide plate, and a mold frame capable of fixing the constituent elements into desired placements and alignments relative to one another. While assembling the mold frame with the bottom chassis, there is a problem in that a defect may occur. For example, recently, with tendency to slimness, when the thickness of the mold frame is thinly formed, problems such as peeling (delamination) or bending (warping) may occur. Further, when the mold frame is affixed to the bottom chassis by using a hook, a part of the mold frame may become peeled (delaminated) and in the process may generate undesired debris (e.g., foreign substances).

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding invention dates of subject matter disclosed herein.

### SUMMARY

The present disclosure of invention provides a bottom chassis for a display device and a display device including the same and having an advantage of being able to alignably affix constituent elements to the bottom chassis while omitting an intermediate mold frame.

An exemplary embodiment provides a bottom chassis for a display device, including: a bottom surface; a plurality of sidewall surfaces extended and bent from the bottom surface; and a plurality of ceiling surfaces extended and bent from a subset of the plurality of sidewall surfaces, in which a subset of an opposed two of the plurality of ceiling surfaces is extended from a correspondingly opposed two sidewall surfaces which face each other among the plurality of sidewall surfaces.

The bottom surface may be formed in a quadrangle shape, and the ceiling surfaces may not be formed at the remaining two sidewall surfaces among the plurality of sidewall surfaces.

The bottom surface may be formed in a quadrangle shape including two long sides and two short sides, and the ceiling surfaces may be extended from the two sidewall surfaces positioned at the two long sides.

The bottom surface may be formed in a quadrangle shape including two long sides and two short sides, and the ceiling surfaces may be extended from the two sidewall surfaces positioned at the two short sides.

A height of the sidewall surface positioned at a corner portion where a respective two of the sidewall surfaces meet may be larger than a height of the sidewall surfaces positioned at the rest portions of the bottom chassis.

Another exemplary embodiment provides a display device, including: a bottom chassis including a bottom surface, a plurality of sidewall surfaces extended and bent from the bottom surface, and a plurality of ceiling surfaces extended and bent from the plurality of sidewall surfaces; a backlight assembly received in the bottom chassis; and a display panel formed on the backlight assembly, in which the ceiling surfaces are extended from two sidewall surfaces which face each other among the plurality of sidewall surfaces.

The bottom surface may be formed in a quadrangle shape, and the ceiling surface may not be formed at the remaining two sidewall surfaces among the plurality of sidewall surfaces.

The backlight assembly may include a light guide plate (LGP) received in the bottom chassis, and an upper surface of two edges of the light guide plate which face each other may be covered by the opposed ceiling surfaces of the bottom chassis.

The backlight assembly may further include a light source disposed at one sidewall surface of the light guide plate.

The backlight assembly may further include a plurality of optical sheets disposed on the light guide plate.

The display panel may be fixed to the ceiling surfaces of the bottom chassis.

The display device may further include an adhesive member positioned between the display panel and the ceiling surfaces of the bottom chassis.

The adhesive member may include a double-sided adhesive tape.

The display device may further include a light blocking member formed at the display panel and the edge of the bottom chassis.

The light blocking member may be formed to cover the edge of the upper surface of the display panel, the sidewall surface of the display panel, the sidewall surface of the bottom chassis, and the edge of the lower surface of the bottom chassis.

The light blocking member may include a single-sided tape.

The bottom surface may be formed in a quadrangle shape including two long sides and two short sides, and the ceiling surfaces may be extended from the two sidewall surface positioned at the two long sides.

The bottom surface may be formed in a quadrangle shape including two long sides and two short sides, and the ceiling surfaces may be extended from the two sidewall surface positioned at the two short sides.

A height of the sidewall surface positioned at a corner portion where sidewall surfaces meet each other may be larger than a height of the sidewall surfaces positioned at the rest of the portions of the bottom chassis.

The sidewall surface positioned at a portion where the plurality of sidewall surfaces meets each other may be formed to cover the sidewall surfaces of the display panel.

As described above, the bottom chassis for a display device and the display device including the same according to the exemplary embodiments of the present disclosure of invention have the following effects: In the bottom chassis for a display device and the display device including the same according to the exemplary embodiments of the present disclosure of invention, it is possible to fix the constituent elements by using the bottom chassis and by omitting an intermediate mold frame.

### BRIEF DESCRIPTION OF THE DRAWINGS

FIG. 1 is a cross-sectional view illustrating a display device according to an exemplary embodiment of the present disclosure of invention.

FIG. 2 is a top plan view illustrating a bottom chassis of the display device according to the exemplary embodiment.

FIG. 3 is a cross-sectional view illustrating the bottom chassis of the display device of FIG. 2 taken along line III-III.

FIG. 4 is a cross-sectional view illustrating the bottom chassis of the display device of FIG. 2 taken along line IV-IV.

FIGS. 5 to 9 are cross-sectional views illustrating an assembling process of inserting constituent parts into the bottom chassis of the display device in accordance with an exemplary embodiment.

FIG. 10 is a plan view illustrating a bottom chassis for a display device according to another exemplary embodiment of the present invention.

FIG. 11 is a cross-sectional view illustrating the bottom chassis of the display device of FIG. 10 taken along line XI-XI.

FIG. 12 is a cross-sectional view illustrating the bottom chassis of the display device of FIG. 10 taken along line XII-XII.

FIG. 13 is a plan view illustrating a bottom chassis for a display device according to yet another exemplary embodiment.

FIG. 14 is a cross-sectional view illustrating the bottom chassis of the display device of FIG. 13 taken along line XIV-XIV.

FIG. 15 is a cross-sectional view illustrating the bottom chassis of the display device of FIG. 13 taken along line XV-XV.

FIG. 16 is a cross-sectional view illustrating a display device according to a further exemplary embodiment in accordance with the present disclosure of invention.

### DETAILED DESCRIPTION

The present teachings will be described more fully hereinafter with reference to the accompanying drawings, in which exemplary embodiments of the present disclosure of invention are shown. As those skilled in the art would realize in light of this disclosure, the described embodiments may be modified in various different ways, all without departing from the spirit or scope of the present teachings.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

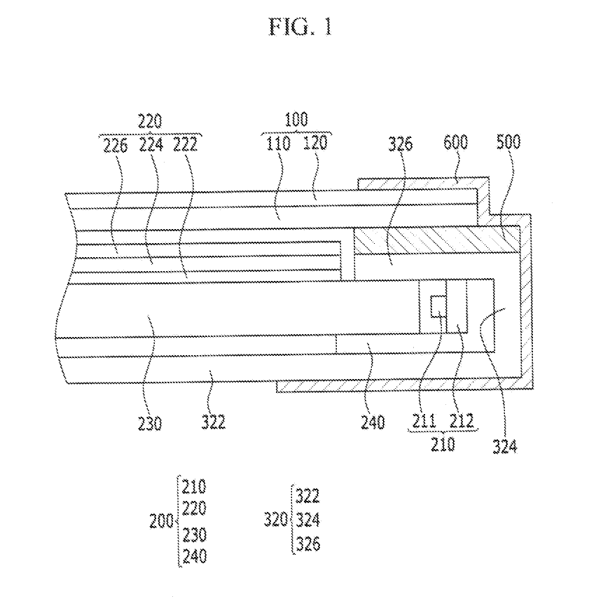

First, a display device according to a first exemplary embodiment in accordance with the present disclosure of invention will be described below with reference to FIG. 1.

FIG. 1 is a cross-sectional view illustrating a display device according to an exemplary embodiment.

The display device according to the exemplary embodiment has its major components, a display panel 100 configured for displaying an image, a backlight assembly 200 configured for supplying light to the display panel 100, a bottom chassis 320 configured for receiving and containing the display panel 100 and the backlight assembly 200 while not requiring a mold frame for affixing and aligning the parts of the display panel 100 and the backlight assembly 200 relative to one another.

The display panel 100 may be a liquid crystal display panel (LCD), but is not limited thereto, and may use various other display technologies that employ backlighting such as an electrophoretic display panel (EDP).

When the liquid crystal display panel is used as the display panel 100, the display panel 100 is formed by spacing apart facing and bonding together a first substrate 110 and a second substrate 120 with a ring-like sealant where a liquid crystal layer (not illustrated) is introduced into the volume bounded by the first substrate 110, the second substrate 120 and the sealant (not shown). Although not further illustrated, a plurality of gate lines and data lines, and thin film transistors connected thereto are formed on the first substrate 110. Further, when respective ones of the thin film transistors (TFTs) are turned on by a gate-on signal being applied from the corresponding gate line, the signal which is then applied along the corresponding data line is charged onto the corresponding pixel electrode driven by that TFT. A common electrode may be formed on the first substrate 110 or on the second substrate 120, and driven by a reference voltage whereby an electric field is formed between the charged pixel electrode and the common electrode to control alignment of liquid crystal molecules of the liquid crystal layer interposed between the pixel electrode and the corresponding portion of the common electrode. Accordingly, light input from the backlight assembly 200 may be controlled for each pixel electrode to thereby form a displayed image.

The backlight assembly 200 includes an edge-type light source unit 210 supplying light from a side portion of the assembly, a light guide plate (LGP) 230 having an incident side adjacent to the edge-type light source unit 210 and having internal means (not shown, e.g., internal reflection surfaces) configured for guiding the edge-received light that is emitted from the light source unit 210 uniformly to the display panel 100, and an optical sheet 220 disposed on the light guide plate 230 for improving uniformity and/or crispness of the LGP re-directed edge light.

The light source unit 210 includes a light source 211 disposed adjacent to a corresponding edge of the LGP 230 and below an outer boundary of a display area of the display panel 100 where the light source 211 is controlled to generate an appropriate amount and/or kind (e.g., color) of light. The light source 211 may be mounted on a combination of heat sink and printed circuit board 212 on which there is disposed wiring and optional control electronics.

The light source 211 may be configured by a plurality of emission members, and the emission members may be configured by, for example, as light emitting diodes (LEDs) of different colors, for example Red, Green, Blue and/or White.

The printed circuit board 212 is electrically connected with the light source 211 to supply signals driving the light source 211 to the light source 211.

The light source unit 210 typically generates heat when generating light, and a heat-sinking extrusion bar 240 is typically provided adjacent to the light source unit 210 and in thermal communicates with the printed circuit board 212 for providing improved heat dissipation. The extrusion bar 240 may be made of a material having high heat dissipation performance, such as a conductive metal, for example aluminum.

The light guide plate 230 is disposed to be adjacent to the light source unit 210. The light emitted from the light source unit 210 is incident to the sidewall surface of the light guide plate 230 before it is re-directed within the LGP to be emitted out of the upper surface of the LGP. In this case, the light guide plate 230 may allow the incident light to be uniformly diffused and emitted entirely to the upper surface.

The optical sheet 220 increases collection efficiency of the light emitted from the upper surface of the LGP 230 and allows the light to have a more uniform distribution over the entire area of the panel's display area. The optical sheet 220 may be configured by a plurality of various sheets, and for example, may include a diffuser sheet 222, a prism sheet 224, and a protecting sheet 226 which are sequentially laminated one on the next in the recited order.

The diffuser sheet 222 diffuses the light emitted from the combination of the light source unit 210 and LGP 230. The prism sheet 224 collects the light diffused from the diffuser sheet 222 in a direction vertical to the plane of the display panel 100. The light passing through the prism sheet 224 is almost vertically incident to the display panel 100. Further, the protecting sheet 226 may be disposed on the prism sheet 224 and protects the prism sheet 224 from external impact and/or contaminants.

Hereinabove, the optical sheet 220 in which the diffuser sheet 222, the prism sheet 224, and the protecting sheet 226 are included one by one is exemplified, but the present teachings are not limited thereto. The optical sheet 220 may use at least one of the diffuser sheet 222, the prism sheet 224, and the protecting sheet 226 of which a plurality of sheets is stacked, and if necessary, any one sheet may be omitted.

The bottom chassis 320 is configured to affixing-wise and aligning-wise receive the constituent components of the display panel 100 and of the backlight assembly 200. More specifically, the bottom chassis 320 may be made of a material having high stiffness so as to protect the display panel 100 and the backlight assembly 200 from external impact.

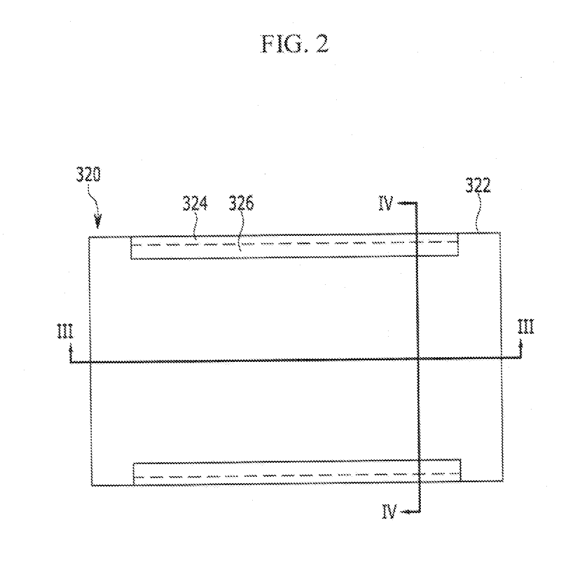

Hereinafter, the bottom chassis 320 of the display device according to the exemplary embodiment invention will be further described with reference to FIGS. 2 to 4.

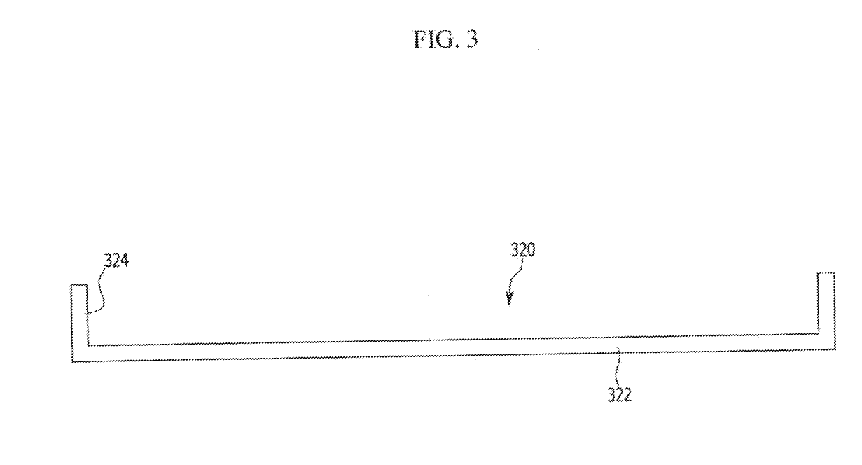

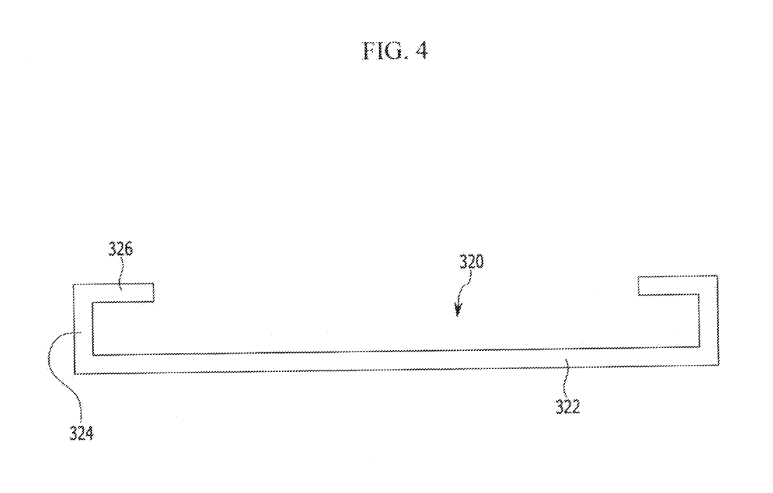

FIG. 2 is a plan view illustrating a bottom chassis 320 of the display device according to the first exemplary embodiment. FIG. 3 is a cross-sectional view illustrating the bottom chassis of the display device of FIG. 2 taken along line III-III. FIG. 4 is a cross-sectional view illustrating the bottom chassis of the display device of FIG. 2 taken along line IV-IV.

More specifically, the bottom chassis 320 has a partially open at the top configuration whereby the light source unit 210 may be slid in from the top and into an interior portion of the bottom chassis 320 for retention therein. Yet more specifically, the bottom chassis 320 includes a bottom surface 322, a plurality of sidewall surfaces 324 extended and bent from the bottom surface 322, and a plurality of ceiling surfaces 326 extended and bent from respective ones of a subset of the sidewall surfaces 324.

The bottom surface 322 may be formed substantially in a quadrangle shape, and particularly, as a quadrangle including two opposed long sides and two opposed short sides.

The sidewall surfaces 324 are extended from respective edges of the bottom surface 322 and are bent to be substantially vertical to the major plane of the bottom surface 322. The sidewall surfaces 324 may be formed as four respective and full length sidewalls so as to fully surround all edges of the bottom surface 322.

The ceiling surfaces 326 are extended from a subset of two opposed sidewall surfaces 324 which face each other. Ceiling surfaces 326 are not formed as extending from the remaining other two sidewall surfaces 324. For example, the bottom surface 322 is configured by two long sides and two short sides, and the ceiling surfaces 326 may be extended from the sidewall surfaces 324 positioned at the two long sides. In this case, the ceiling surfaces 326 are not formed as extending from the shorter sidewall surfaces 324 positioned at the two short sides of the bottom surface 322.

Accordingly, as illustrated in FIG. 3, in a cross section cut in a direction parallel to the long side, both ends of the bottom chassis 320 may each be formed to have a respective and substantially ‘L’-lettered shape. Further, as illustrated in FIG. 4, in a cross section cut in a direction parallel to the short side, both ends of the bottom chassis 320 may be each formed to have a respective and substantially ‘C’-lettered shape.

As illustrated in FIG. 2, the ceiling surfaces 326 may be extended from only partial lengths of the two long sidewall surfaces 324 rather from the entire lengths of these two long sidewall surfaces 324 which face each other. That is, the ceiling surfaces 326 may be not formed at both end edges of the sidewall surfaces 324. However, the present disclosure of invention is not limited thereto, and the ceiling surface 326 may instead be extended from the full lengths of the opposed two sidewall surfaces 324 from which they extend.

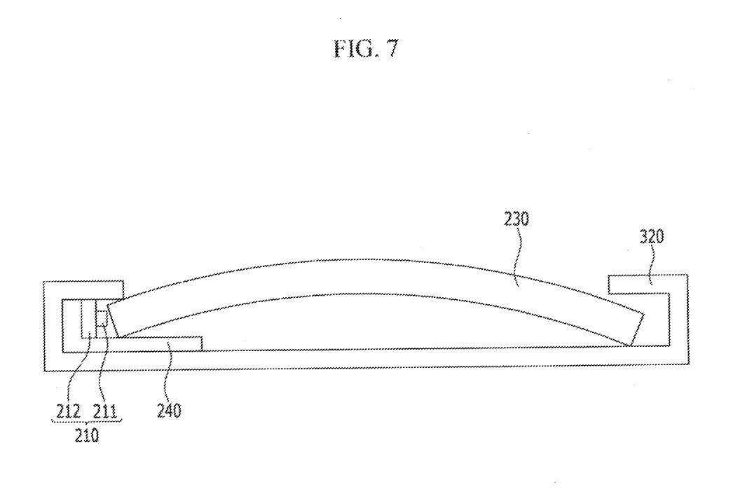

Referring back to FIG. 1, the light source unit 210 is disposed inside the sidewall surfaces 324 of the bottom chassis 320 so as to be retained at its upper and lower portions respectively by a corresponding ceiling surface 326 and an opposed portion of the bottom surface 322. The light guide plate 230 is disposed to be adjacent to the light source unit 210 and retained between the corresponding ceiling surface 326 and an opposed portion of the extrusion bar 240. The light guide plate 230 is alignably disposed so that the light emitted from the edge-type light source unit 210 is efficiently coupled to the sidewall surface of the light guide plate 230. In one embodiment, at least the interior surfaces of the corresponding ceiling surface 326 and the opposed portion of the extrusion bar 240 are formed to be highly reflective. In other words, an upper surface of the edge of the light guide plate 230 is covered by the corresponding ceiling surface and a lower surface of the edge of the light guide plate 230 is correspondingly covered by the opposed portion of the bottom surface 322 of the bottom chassis 320. The light guide plate 230 may be formed substantially in a quadrangle shape, and the upper surfaces of an opposed two edges of the light guide plate 230 may be covered by and affixed to the bottoms of the opposed ceiling surfaces 326 of the bottom chassis 320. As will be seen in FIG. 7, the light guide plate 230 may be made flexible such that it is easily inserted under and then affixed at its opposed ends between the bottom surface 322 and the ceiling surfaces 326 of the bottom chassis 320.

Hereinabove, an edge-type backlight system in which the light source unit 210 is disposed below and adjacent to one edge of the display area of the display panel 100 is described, but the present disclosure of invention is not limited thereto, and a direct-type backlight wherein the light sources are attached to the ceiling portion 326 of the bottom chassis 320 may be used.

The display panel 100 is affixed and aligned to a first part (e.g., top surface) of the ceiling portion 326 of the bottom chassis 320 while the backlighting subsystem is affixed and aligned to a second part (e.g., bottom surface) of the ceiling portion 326 of the bottom chassis 320. More specifically, part (e.g., 110) of the display panel 100 may be substantially directly disposed on and affixed to a top surface of the ceiling portion 326 of the bottom chassis 320. An adhesive member 500 (e.g., a heat activated one) may be formed between the display panel 100 and the upper ceiling surface 326 of the bottom chassis 320. The adhesive member 500 may include a double-sided adhesive tape, and the display panel 100 may be thus affixed to the bottom chassis 320, where pre-adhesion alignment is provided using the next-described, rigid and pre-formed part 600.

An opaque and thus light blocking member 600 may be formed to control spacing and alignment as between one or more edges of the display panel 100 and a corresponding one or more edges of the bottom chassis 320. The light blocking member 600 may serve the dual functions of blocking leakage light and providing for pre-adhesion (e.g., prior to heat activation of the adhesives) alignment as between the display panel 100 and the bottom chassis 320. A part of light emitted from the light source 211 may be reflected so as to be undesirably leaked from the edge of the upper surface or the sidewall surface of the display panel 100. In order to prevent this, the light blocking member 600 may be formed as an opaque member to cover the edge of the upper surface of the display panel 100 and the sidewall surface of the display panel 100. Further, the light blocking member 600 may be further formed to cover the sidewall surface of the bottom chassis 320 and the edge of the lower surface of the bottom chassis 320. In one embodiment, the light blocking member 600 includes a single-sided and heat-activated adhesive tape including a light blocking material.

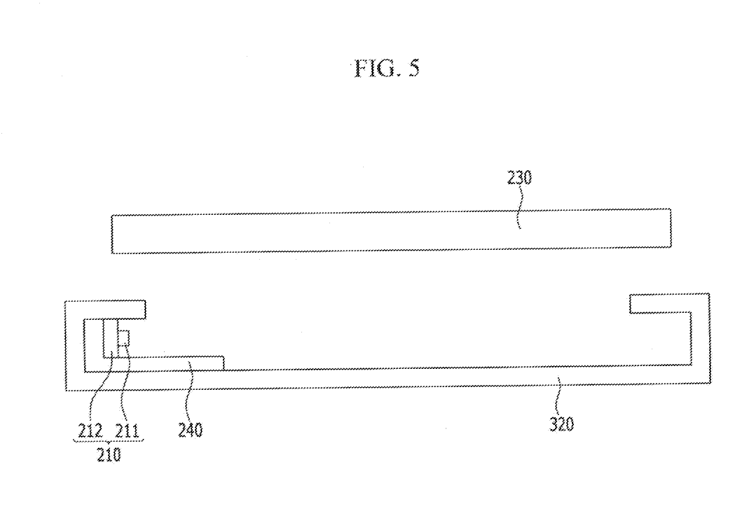

Hereinafter, an assembling process of a display device according to an exemplary embodiment will be described with reference to FIGS. 5 to 9.

FIGS. 5 to 9 are process cross-sectional views illustrating an assembling process of a display device according to the exemplary embodiment of FIGS. 1-4.

First, as illustrated in FIG. 5, the light source unit 210 and the extrusion bar 240 are fixed to an interior portion of the bottom chassis 320 where the said interior portion include the ceiling portion 326 as one of its boundaries. First, the light source unit 210 is fixed to the extrusion bar 240, the extrusion bar 240 is inserted into the bottom chassis 320 and then may be fixed to the sidewall surfaces 324 or the bottom surface 322 of the bottom chassis 320 by using a screw and/or other appropriate fastening means.

Next, the light guide plate 230 is prepared. Since a size of the light guide plate 230 is larger than a drop-in space available between the opposed two ceiling surfaces 326 of the bottom chassis 320, the light guide plate 230 may not be assembled by a general drop-down method.

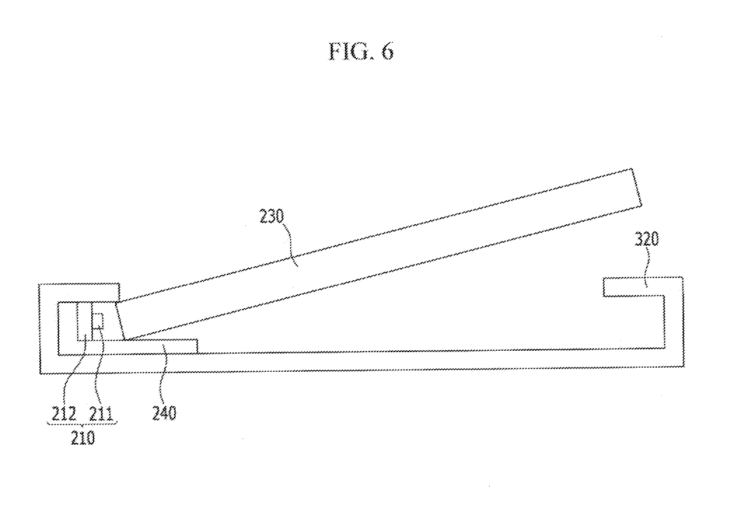

Instead, a tilt and flex method may be used. As illustrated in FIG. 6, one edge of the light guide plate 230 is positioned at one edge of the bottom chassis 320. One edge of the light guide plate 230 is inserted between the bottom surface 322 and the ceiling surface 326 of one edge of the bottom chassis 320 and thus one edge of the light guide plate 230 is guided into that portion of the bottom chassis 320.

As illustrated in FIG. 7, the light guide plate 230 is made of a flexible material and is bent as shown so that the other edge of the light guide plate 230 may be guided into insertion within the interior portion at the other side of the bottom chassis 320. Thus, even though the size of the light guide plate 230 is larger than the drop-in space between two ceiling surfaces 326 of the bottom chassis 320, the light guide plate 230 may be bent to be inserted into the opposed interior portions defined by the opposed ceiling surfaces 326 of the bottom chassis 320.

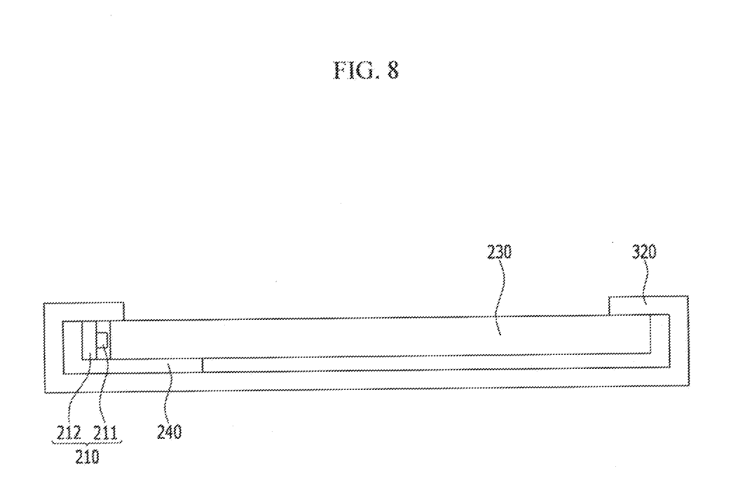

As illustrated in FIG. 8, when stress applied to the resilient light guide plate 230 is removed, the light guide plate 230 is restored (relaxes back) into its original planar state. That is, the bent light guide plate 230 is unbent. The other edge of the light guide plate 230 is inserted between the bottom surface 322 and the ceiling surface 326 of the other edge of the bottom chassis 320 and thus the other edge of the light guide plate 230 is held within the bottom chassis 320.

Although not illustrated, one or more elastic buffer members may be further formed at the sidewall surfaces 324 of the bottom chassis 320 which correspond to one edge and the other edge of the light guide plate 230. The buffer member(s) may serve to prevent the light guide plate 230 from being damaged while being fixed to the bottom chassis 320, and the buffer member(s) may buffer expansion and contraction of the light guide plate 230. In one embodiment, the top surface of the flattened LGP 230, at opposed edges thereof, is abutted against the under sides of the opposed ceiling portions 326 such that the height of the LGP 230 is established in accordance with the heights of the opposed ceiling portions 326. The abutment may be the result of elastic pressure and/or adhesion by use of an appropriate adhesive (not shown).

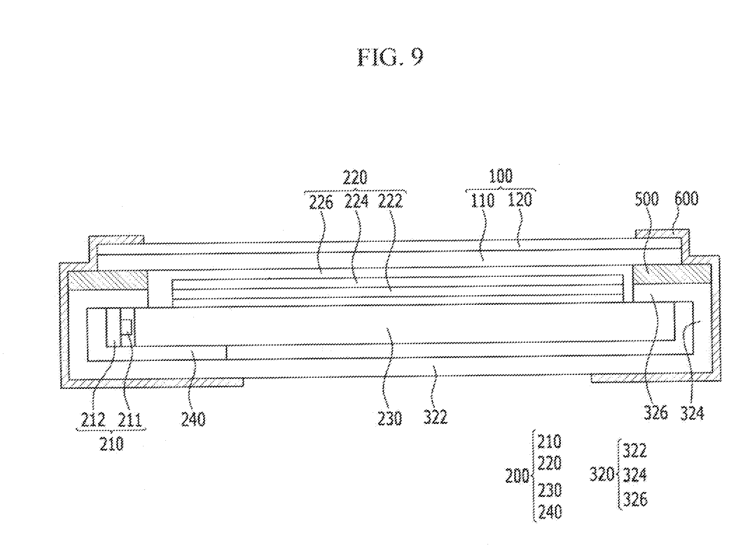

As illustrated in FIG. 9, the optical sheet 220 is disposed on the already, height-wise aligned light guide plate 230, and the display panel 100 is disposed above the optical sheet 220 while being height-wise aligned to the top surfaces of the opposed ceiling portions 326. In the illustrated embodiment, the double-sided adhesive member 500 is formed on the ceiling surfaces 326 of the bottom chassis 320, and the display panel 100 is placed onto the adhesive member 500 to enable fixing the display panel 100 to the bottom chassis 320 by way of selectively activated adhesion (e.g., heat activated adhesion). Next, the light blocking member 600 is positioned at edges of the display panel 100 and the corresponding edges of the bottom chassis 320. The shape of the pre-formed light blocking member 600 may provide the desired alignment between the corresponding edges before the selectively activated adhesion function (e.g., heat activated adhesion) of the adhesive member 500 is activated to thereby alignably affix both of the display panel 100 and the bottom chassis 320 to the surfaces of the opposed ceiling portions 326. Although edge lighting from one edge of the LGP 230 is described above, it is within the contemplation of the present disclosure to have edge lighting provided from two or more edge of the LGP 230 and in such a case, at least an additional light source unit would be provided under the opposed ceiling portion as well as under the first ceiling portion.

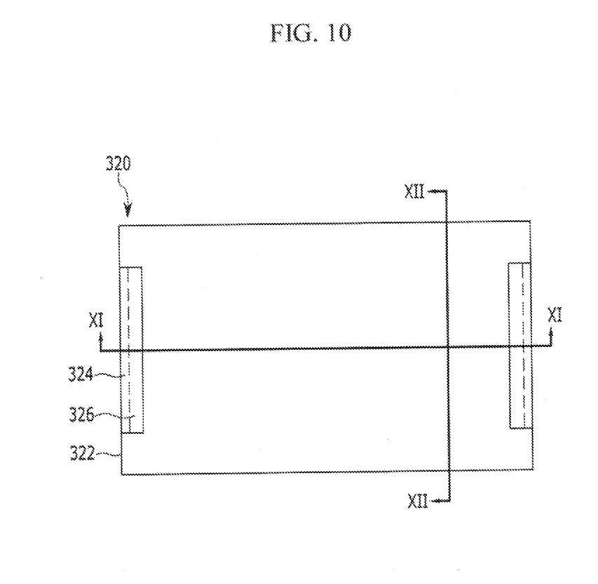

Next, another embodiment of a bottom chassis for a display device according to an exemplary embodiment of the present disclosure invention will be described below with reference to FIGS. 10 to 12.

Since a bottom chassis for a display device according to this second exemplary embodiment of FIGS. 10 to 12 is almost the same as the a bottom chassis of the display device according to the exemplary embodiment of FIGS. 2 to 4, repeated description of all the details is omitted. The second exemplary embodiment is different from the first one in that the opposed ceiling portions are extended from the two short sides rather than the longer ones.

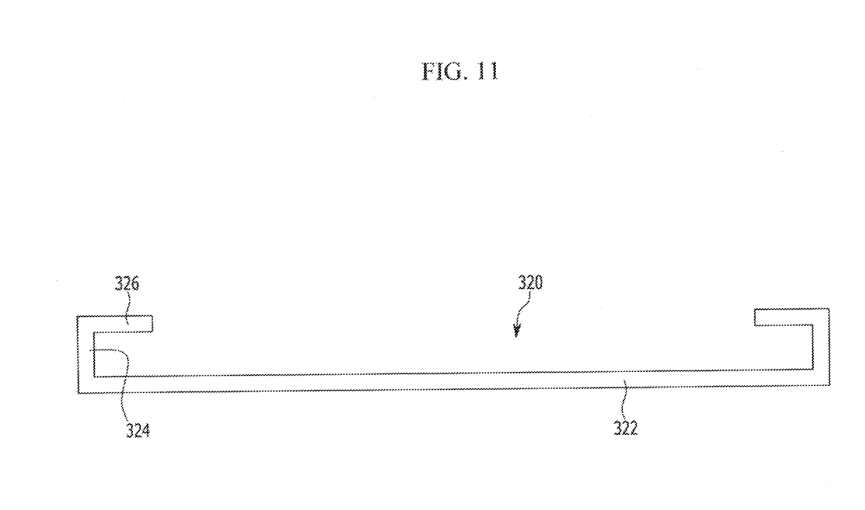

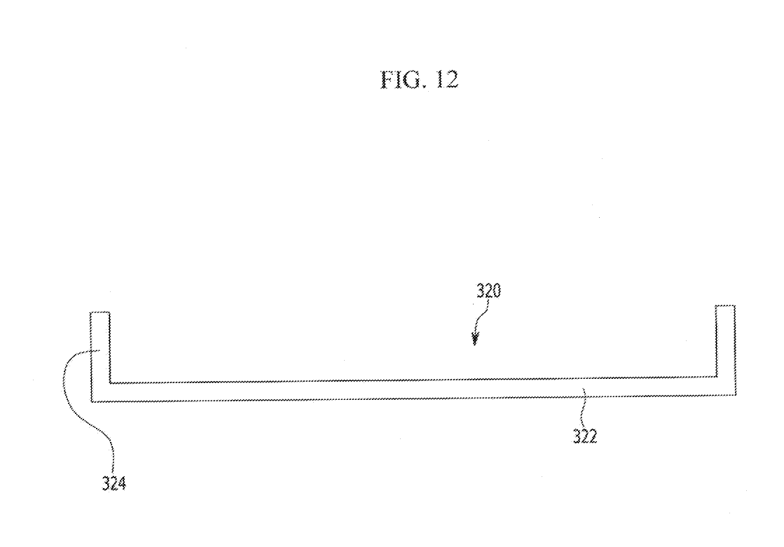

More specifically, FIG. 10 is a top plan view illustrating a bottom chassis for a display device according to the second exemplary embodiment. FIG. 11 is a cross-sectional view illustrating the bottom chassis of the display device of FIG. 10 taken along line XI-XI. FIG. 12 is a cross-sectional view illustrating the bottom chassis of the display device of FIG. 10 taken along line XII-XII.

The bottom chassis 320 of this second embodiment includes a bottom surface 322, a plurality of sidewall surfaces 324 extended and bent from the bottom surface 322, and a plurality of ceiling surfaces 326 extended and bent from the plurality of sidewall surfaces 324.

The ceiling surfaces 326 are extended from two sidewall surfaces 324 which face each other among the plurality of sidewall surfaces 324. The ceiling surfaces 326 are not formed at the remaining two sidewall surfaces 324 except for the two sidewall surfaces 324 which face each other. For example, the bottom surface 322 is configured by two long sides and two short sides, and the ceiling surface 326 may be extended from the sidewall surfaces 324 positioned at the two short sides. In this case, the ceiling surface 326 is not formed at the sidewall surfaces 326 positioned at the two long sides.

Accordingly, as illustrated in FIG. 11, in a cross section cut in a direction parallel to the long side, both ends of the bottom chassis 320 may be formed substantially in an ‘C’-lettered shape. Further, as illustrated in FIG. 12, in a cross section cut in a direction parallel to the short side, both ends of the bottom chassis 320 may be formed substantially in an ‘L’-lettered shape.

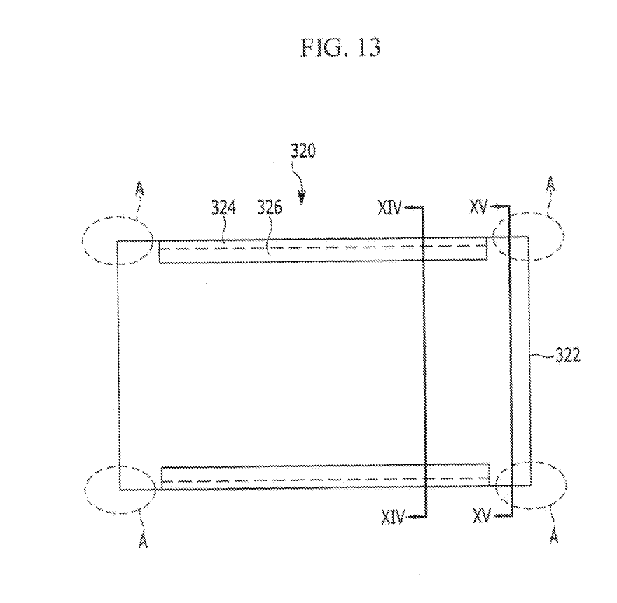

Next, a display device according to a third exemplary embodiment of the present disclosure will be described below with reference to FIGS. 13 to 16.

Since a display device according to the third exemplary embodiment of FIGS. 13 to 16 is almost the same as the display device according to the other exemplary embodiments, the fully detailed description thereof is omitted. The exemplary embodiment is different from the above exemplary embodiments in that respective heights of the sidewall surfaces of the bottom chassis 320 vary and hereinafter, that difference will be described in more detail.

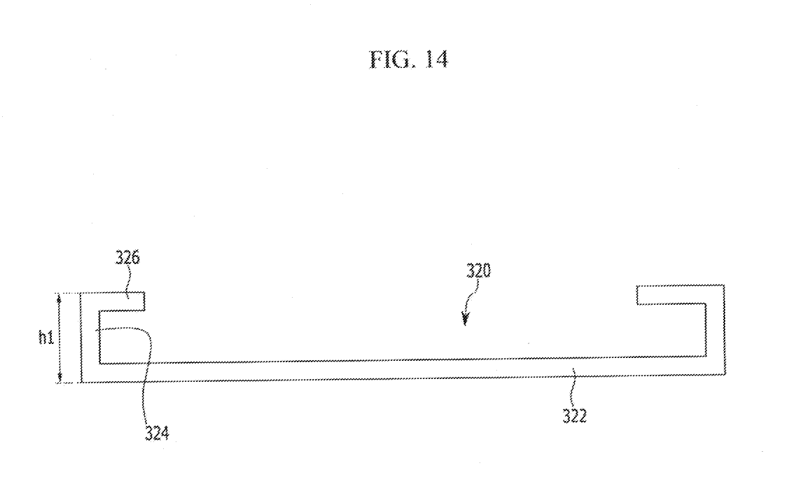

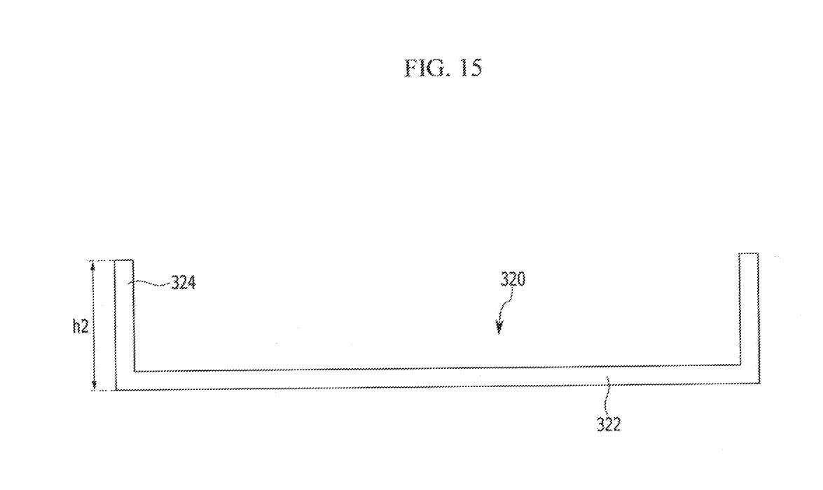

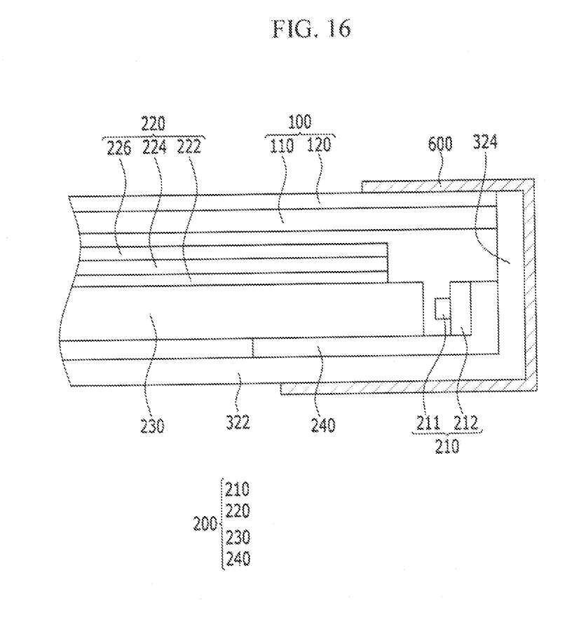

FIG. 13 is a plan view illustrating a bottom chassis for a display device according to an exemplary embodiment of the present invention, FIG. 14 is a cross-sectional view illustrating the bottom chassis of the display device of FIG. 13 taken along line XIV-XIV. FIG. 15 is a cross-sectional view illustrating the bottom chassis of the display device of FIG. 13 taken along line XV-XV. FIG. 16 is a cross-sectional view illustrating a display device according to an exemplary embodiment.

A bottom chassis 320 of the display device according to the third exemplary embodiment includes a bottom surface 322, a plurality of sidewall surfaces 324 extended and bent from the bottom surface 322, and a plurality of ceiling surfaces 326 extended and bent from a subset of the sidewall surfaces 324.

A respective height h2 of the sidewall surfaces 324 where the ceiling portions are not present, for example as exemplified in chassis corner portion A (region A) where the plurality of sidewall surfaces 324 of the bottom chassis 320 meet each other is larger than a respective height h1 of the sidewall surfaces 324 positioned where the ceiling portions are present, and in one embodiment, also at the rest of the portions except for the corner regions A of the bottom chassis 320. In FIG. 14, the sidewall surface 324 positioned at the rest portion except for the region A is illustrated, and in FIG. 15, the sidewall surface 324 positioned in the region A is illustrated.

As illustrated in FIG. 16, since the sidewall surface 324 positioned in the portion (region A) where the plurality of sidewall surfaces 324 of the bottom chassis 320 meet each other is formed to be higher, the sidewall surface 324 of the bottom chassis 320 positioned in the region A may cover the sidewall surface of the display panel 100. Accordingly, the display panel 100 may be affixed to the bottom chassis 320 more strongly. Further, the bottom chassis 320 is formed to cover the corners of the display panel 100 to prevent the display panel 100 from being damaged by external impact.

While this disclosure of invention has been described in connection with what are presently considered to be practical exemplary embodiments, it is to be understood that the present teachings are not limited to the disclosed embodiments, but, on the contrary, the disclosure is intended to cover various modifications and equivalent arrangements included within the spirit and scope of the present teachings.

What is claimed is:

1. A bottom chassis for a display device, comprising:
a bottom surface;
a plurality of sidewall surfaces extended and bent from the bottom surface; and
a plurality of ceiling surfaces extended and bent from a subset of the plurality of sidewall surfaces,
wherein the plurality of ceiling surfaces include two opposed ones extended from a respective two of the sidewall surfaces which opposingly face each other from among the plurality of sidewall surfaces.

2. The bottom chassis for a display device of claim 1, wherein:
the bottom surface is formed in a quadrangle shape, and
the ceiling surfaces are not formed at the remaining two sidewall surfaces among the plurality of sidewall surfaces.

3. The bottom chassis for a display device of claim 1, wherein:
the bottom surface is formed in a quadrangle shape including two long sides and two short sides, and
the ceiling surfaces are extended from the two sidewall surfaces positioned at the two long sides.

4. The bottom chassis for a display device of claim 1, wherein:
the bottom surface is formed in a quadrangle shape including two long sides and two short sides, and
the ceiling surfaces are extended from the two sidewall surfaces positioned at the two short sides.

5. The bottom chassis for a display device of claim 1, wherein:
a height of the sidewall surface positioned at a portion where the plurality of sidewall surfaces meets each other is larger than a height of the sidewall surface positioned at the rest of the portions.

6. A display device, comprising:
a bottom chassis including a bottom surface, a plurality of sidewall surfaces extended and bent from the bottom surface, and a plurality of ceiling surfaces extended and bent from a subset of the plurality of sidewall surfaces;
a backlight assembly received in the bottom chassis; and
a display panel formed on the backlight assembly,
wherein the ceiling surfaces include two opposed ones respectively extended from two opposed sidewall surfaces which face each other among the plurality of sidewall surfaces.

7. The display device of claim 6, wherein:
the bottom surface is formed in a quadrangle shape, and
the ceiling surfaces are not formed at the remaining two sidewall surfaces among the plurality of sidewall surfaces.

8. The display device of claim 6, wherein:
the backlight assembly includes
a light guide plate received in the bottom chassis, and
respective upper surfaces of two opposed edges of the light guide plate are covered by the opposed ceiling surfaces of the bottom chassis.

9. The display device of claim 8, wherein:
the backlight assembly further includes
a light source disposed at one sidewall surface of the light guide plate.

10. The display device of claim 9, wherein:
the backlight assembly further includes
a plurality of optical sheets disposed on the light guide plate.

11. The display device of claim 6, wherein:
the display panel is fixed to the ceiling surfaces of the bottom chassis.

12. The display device of claim 11, further comprising:
an adhesive member positioned between the display panel and the ceiling surfaces of the bottom chassis.

13. The display device of claim 12, wherein:
the adhesive member includes a double-sided adhesive tape.

14. The display device of claim 12, further comprising:
a light blocking member formed at the display panel and the edge of the bottom chassis.

15. The display device of claim 14, wherein:
the light blocking member is formed to cover the edge of the upper surface of the display panel, the sidewall surface of the display panel, the sidewall surface of the bottom chassis, and the edge of the lower surface of the bottom chassis.

16. The display device of claim 15, wherein:
the light blocking member includes a single-sided tape.

17. The display device of claim 16, wherein:
the bottom surface is formed in a quadrangle shape including two long sides and two short sides, and
the ceiling surfaces are extended from the two sidewall surfaces positioned at the two long sides.

18. The display device of claim 16, wherein:
the bottom surface is formed in a quadrangle shape including two long sides and two short sides, and
the ceiling surfaces are extended from the two sidewall surfaces positioned at the two short sides.

19. The display device of claim 16, wherein:
a height of the sidewall surface positioned at a portion where the plurality of sidewall surfaces meets each other is larger than a height of the sidewall surface positioned at the rest portion.

20. The display device of claim 19, wherein:
each sidewall surface positioned at a portion where a respective two of the plurality of sidewall surfaces meet each other is formed to cover the respective corner sidewall surface of the display panel.
